(19) United States
(12) Patent Application Publication
(10) Pub. No.: US 2011/0100607 A1
(43) Pub. Date: May 5, 2011

(54) HEAT DISSIPATING CAVITY OF LOOPED HEAT PIPE

(75) Inventors: JI LI, Beijing (CN); Da-Ming Wang, Beijing (CN)

(73) Assignee: Beijing AVC Technology Research Center Co., Ltd., Beijing (CN)

(21) Appl. No.: 12/610,650

(22) Filed: Nov. 2, 2009

(51) Int. Cl. F28D 15/04; F28F 7/00; H05K 7/20

(52) U.S. Cl. 165/104.26; 165/185

(57) ABSTRACT

A heat dissipating cavity of looped heat pipe structure includes a cavity made of high thermal conductive material having a plurality of heat dissipating fins on the outside thereof, and looped heat pipes. The heat generated by the heating electronic elements inside the cavity is first effectively conducted to the looped heat pipes, wherefrom to the entire cavity, and finally released out of the system by the plurality of heat dissipating fins. The use of looped heat pipes increases the homogeneity of the cavity's overall temperature and greatly improves the efficiency of heat dissipation.

### BACKGROUND OF THE INVENTION

1. Field of the Invention

The present invention relates to an electronic heat dissipating apparatus and particularly to an electronic heat dissipating apparatus which employs looped heat pipes.

2. Brief Description of Related Art

Existing cavities are mostly made of metal and manufactured by casting. But due to the limitation of existing casting technology, the material used usually has low thermal conductivity coefficient. The heat generated by electronic parts tends to concentrate in one local area, thereby greatly raising the temperature of that local area and causing the temperature of those electronic parts to exceed their tolerance limit. Yet the remaining big area in the cavity, which is away from those heating electronic parts, is far lower in temperature than the said local area. This results in uneven temperature distribution in the cavity and the exterior fins, and seriously compromises the heat dissipating efficiency of the cavity. To solve the foregoing problem, the existing solution is either to increase the thickness of the cavity or to improve its material. But this kind of solution itself leads to other technical problems, such as the overweight of the cavity.

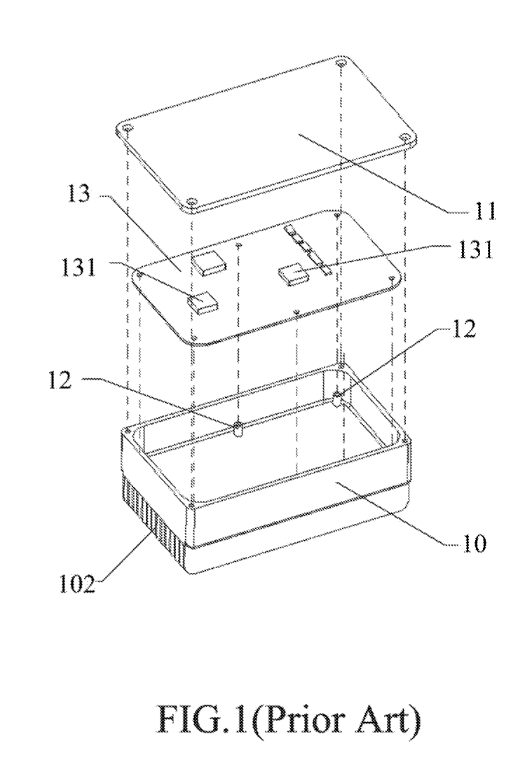

FIG. 1 is an exploded perspective view of a heat dissipating cavity manufactured by existing technology. Referring to FIG. 1, an existing heat dissipating cavity includes a cavity 10, a cover 11, fixed support elements 12, and an electronic board 13. On the exterior surface of the cavity 10 is disposed a plurality of heat dissipating fins 102. Fixed support elements 12 are disposed inside the cavity in accordance with the positioning of the holes and the height of the chips on the electronic board. The function of the cover 11 is to form a closed space, which protects the electronic board from wind, rain, sand, and dust, and which also helps to dissipate heat.

When the electronic board 13 performs, its heating elements 131 (such as CPU, high-power photoelectric parts, radio-frequency electronic parts, or other transistors) will generate a huge amount of heat during calculation. The heat is first conducted to the cavity through the base of the cavity, which is directly in contact with the heating elements, and then released out of the system through the heat dissipating fins. Owing to the limitation of existing manufacturing technology, the material of known cavities has low thermal conductivity coefficient, causing a large amount of heat to concentrate in the small local area where the heat dissipating cavity 10 touches the heating elements 131. The temperature of this small local area is likely to exceed the maximum working temperature limit of the electronic heating elements 131, whereas the remaining big area of the cavity and the heat dissipating fins are too low in temperature to effectively dissipate heat. The effective utilization rate of the fins is therefore rather low. Meanwhile, because the material of the heat dissipating cavity 10 does not effectively accumulate heat, when the heating power of the electronic parts suddenly changes, the amount of accumulated heat will suddenly rise, and the temperature of the electronic heating elements will suddenly rocket, which may damage the electronic parts.

In view of the foregoing considerations, an existing heat dissipating cavity has the following disadvantages:

1. The distribution of temperature in the cavity and the heat dissipating fins is rather uneven, so the cavity's efficiency in dissipating heat is low.

2. When the heating power of the electronic parts suddenly changes, the cavity's thermal response time is longer, which may damage the chips.

In view of the foregoing considerations, the present invention attempts to solve the foregoing problems and improve the foregoing disadvantages.

### SUMMARY OF THE INVENTION

It is an object of this present invention to provide a heat dissipating cavity of looped heat pipe structure which can dissipate heat more efficiently.

It is a further object of the present invention to provide a heat dissipating cavity of looped heat pipe structure which has a faster thermal response time.

With the above objects in mind, the present invention is a heat dissipating cavity of looped heat pipe structure which includes a cavity and looped heat pipes. The cavity is made of high thermal conductive material, and a plurality of heat dissipating fins is disposed on the outside thereof. The pipeline of the looped heat pipes is evenly disposed on the inner surface of the cavity. The heat generated by the heating electronic elements inside the cavity is first effectively conducted to the looped heat pipes, wherefrom to the entire cavity, and finally released out of the system by the plurality of heat dissipating fins. The use of looped heat pipes increases the homogeneity of the cavity's overall temperature and greatly improves the efficiency of heat dissipation.

### BRIEF DESCRIPTION OF THE INVENTION

FIG. 1 is an exploded perspective view of an existing heat dissipating cavity.

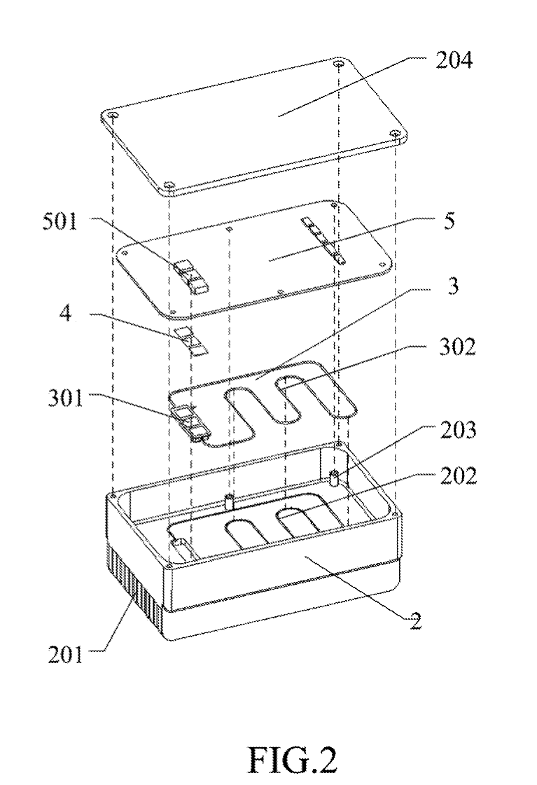

FIG. 2 is an exploded perspective view of the preferred embodiment of the present invention.

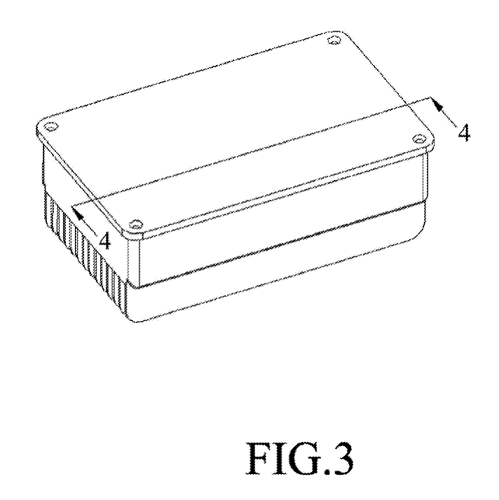

FIG. 3 is an assembled perspective view of the preferred embodiment of the present invention.

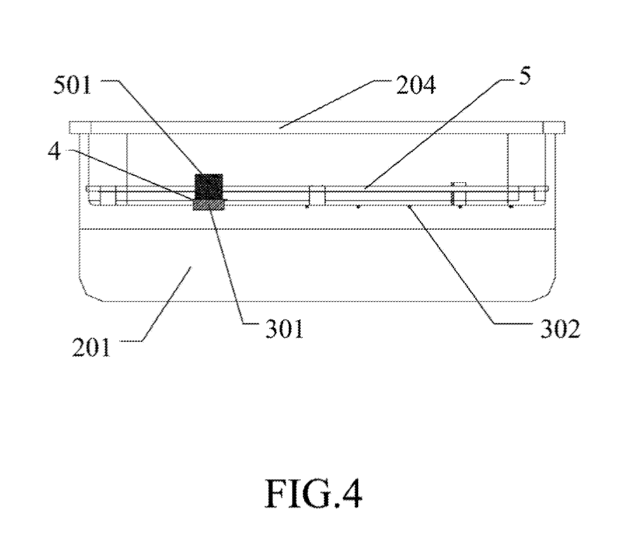

FIG. 4 is a side view of the preferred embodiment of the present invention.

### DETAILED DESCRIPTION OF THE PREFERRED EMBODIMENT

Several aspects of the invention are hereinafter described in detail with reference to FIGS. 2 to 4.

Referring to FIG. 2, the present invention is a heat dissipating cavity of looped heat pipe structure. The preferred embodiment includes a cavity 2, a looped heat pipe 3, and functional accessories (high thermal conductive elements 4 are employed in the present invention). On the outside of the cavity is disposed a plurality of heat dissipating fins 201. On the inner base of the cavity 2 is disposed a groove 202 to hold the looped heat pipe. The present invention is designed for the electronic board 5, whereon are disposed heating elements 501.

In the preferred embodiment of the invention, the looped heat pipe 3 can be disposed in the looped heat pipe groove 202 inside the cavity by welding, heat conductive glue, or screw. The high thermal conductive pads 4 are disposed between the heating elements 501 and the looped heat pipe 3. The heat generated by the heating elements 501 is conducted through the high thermal conductive elements 4 to the looped heat pipe 3, wherefrom evenly conducted to the cavity 2, and released out of the system by the heat dissipating fins 201. The use of the looped heat pipe 3 facilitates even temperature increase across the entire cavity and raises the effective utilization rate of the heat dissipating fins 201, thereby achieving better heat dissipation. With the use of the lighter looped heat pipe 3 rather than a large quantity of metal materials, and a thinner base for the cavity, the cavity 2 of the present invention is much lighter in weight in comparison with any existing cavity.

The application of the present invention is hereinafter described in detail with reference to FIGS. 2, 3, and 4.

The cavity 2 can be made of high thermal conductive materials such as aluminium, other metals, or other compound metals. On the inner base of the cavity is disposed a looped heat pipe groove 202, which corresponds to the shape of the looped heat pipe's pipeline and its cross-section so that the looped heat pipe 3 can be adhered to the groove by welding. To meet the requirements of welding, both the inner and outer surfaces of the cavity 2 are treated with chemical nickel plating, which can also meet the anti-corrosion requirements of the surfaces. Corresponding treatment of the surface has to be done if the looped heat pipe 3 is adhered to the cavity by thermal conductive glue or screws.

The inner structure of the looped heat pipe 3 can be in various forms. The number of the looped heat pipe 3, the distribution shape and cross-section shape of the pipeline 302 are determined by the heating power of the heating elements 501 on the electronic board 5, their maximum working temperature limit, and their structure. In the preferred embodiment of the present invention, at least one looped heat pipe is disposed. To equalize the temperature of the cavity base, the pipeline 302 is designed in the shape as shown in FIG. 2 in accordance with the distribution of the heating amount on the electronic board. The shape of the evaporators 301 on the looped heat pipe 3 is determined by the shape of the heating elements 501; they should completely cover the surface of the heating elements. In the preferred embodiment of the present invention, the looped heat pipe 3 is made of copper or other high thermal conductive materials. Because copper has high thermal accumulation coefficient and thermal conductivity coefficient, the thermal response time of the heat dissipating cavity is short when the heating power of the heating elements 501 suddenly rises. The material of these elements includes but is not limited to such high thermal conductive materials as copper, aluminium, and graphite.

The high thermal conductive elements 4 are as big as or slightly bigger than the heating elements. Their function is to make the contact between the evaporators 301 of the looped heat pipe and the heating elements 501 elastic, efficiently reducing the thermal contact resistance and the requirements of manufacturing precision. It is within the scope of the present invention to replace these elements by the thermal conductive paste which is applied to the surface of copper plates.

The function of the cavity cover 204 is to form a closed space, which protects the electronic hoard from wind, rain, sand, and dust, and which also helps to dissipate heat. In the present invention, in order to improve its efficiency in dissipating heat, the cavity cover 204 can be treated in the same way as the cavity base. Grooves can be disposed on the side of the cavity cover facing the electronic board 5 to hold a certain amount of looped heat pipes, and auxiliary heat dissipating structures such as heat dissipating fins can be disposed on the other side thereof. All the foregoing changes and modifications are within the scope of the present invention.

The electronic board 5 can be screwed onto the fixed support elements 203 and thereby adhered to the inner base of the cavity 2.

In view of the foregoing considerations, the present invention is a heat dissipating cavity of looped heat pipe structure which has the following advantages:

1. It is more efficient in heat dissipation.

2. It has a faster thermal response time.

It is to be understood that the form of our invention herein shown and described is to be taken as a preferred example of the same and that various changes in the method, shape, structure, and installation may be resorted to without departing from the spirit of our invention on the scope of the subjoined claims.

What is claimed is:

1. A heat dissipating cavity of looped heat pipe structure comprising:
a cavity having a plurality of heat dissipating fins disposed on its exterior surface and a base in its inner surface; and
looped heat pipes disposed on the inner base of the cavity, which effectively and evenly conduct the heat generated by heating electronic parts to the entire cavity and then release it out of the system through heat dissipating fins.

2. The heat dissipating cavity of looped heat pipe structure of claim 1 wherein grooves or positioning holes are disposed on the inner base of the cavity to hold looped heat pipes.

3. The heat dissipating cavity of looped heat pipe structure of claim 1 wherein the looped heat pipes include evaporators and pipelines.

4. The heat dissipating cavity of looped heat pipe structure of claim 1 wherein the looped heat pipes are disposed in the looped heat pipe grooves inside the cavity by welding, heat conductive glue, or screw.

5. The heat dissipating cavity of looped heat pipe structure of claim 1 wherein high thermal conductive elements are disposed between heating electronic elements and looped heat pipes.

6. The heat dissipating cavity of looped heat pipe structure of claim 5 wherein the form of high thermal conductive elements includes but is not limited to solid slice or paste.
